(19) United States
(12) Patent Application Publication
(10) Pub. No.: US 2002/0118022 A1
(43) Pub. Date: Aug. 29, 2002

(54) Arc detection

(76) Inventors: Jonathan Samuel Dring, Cheltenham (GB); Ian Bickerton, Cheltenham (GB)

Correspondence Address: CONNOLLY BOVE LODGE & HUTZ LLP, SUITE 800, 1990 M STREET NW, WASHINGTON, DC, 20036-3425, US

(21) Appl. No.: 10/082,170

(22) Filed: Feb. 26, 2002

(30) Foreign Application Priority Data
Feb. 27, 2001 (GB) 0104763.8

(51) Int. Cl. H01H 9/50; G01R 31/08; G01R 31/12

(52) U.S. Cl. 324/536

(57) ABSTRACT

Signals representative of current and voltage in a circuit are processed and compared with stored temporal models models representative of arc faults and events not associated with arc faults. The models may be templates or stochastic models. Alternatively, the processed signals may be supplied to an artificial neural net programmed to recognize features of different arcs. An output may be provided to open a circuit breaker when an arc fault is detected.

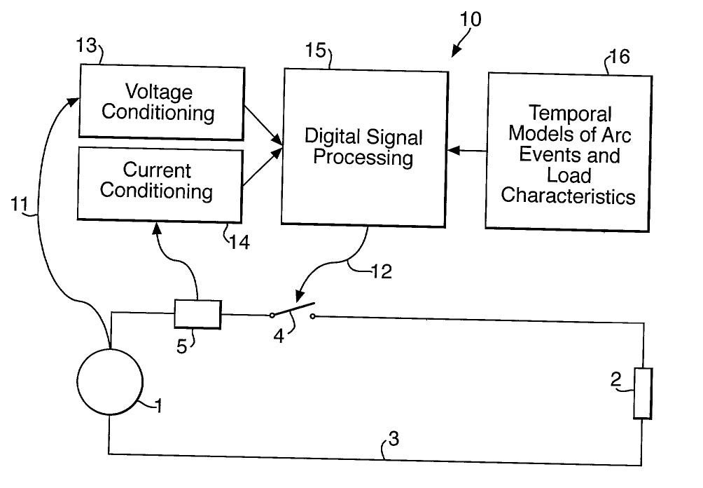

### BACKGROUND OF THE INVENTION

This invention relates to methods and apparatus for detecting arc faults in electrical systems.

Electrical systems may suffer from arcing between parts of the system at different voltages or between a part of the system and earth. The presence of an arc may be indicative of a breakdown in insulation or some other fault. Because arcing prevents proper operation of the system and may cause damage or fire risk, it is important that the arcing be detected rapidly and accurately. It can, however, be difficult to distinguish between arcs caused by faults, such as insulation damage, and arcs produced in normal operation, such as in ac motor commutators, thyristor-controlled loads, switchgear and the like. It is important to minimize the number of false arc alarms produced since these may result in a circuit breaker being tripped and an interruption of power supply to equipment.

U.S. Pat. No. 4,316,139 describes an arc detection system including detectors responsive to vibration and electromagnetic disturbances produced by an arc. EP 639879A, EP 813281A, GB 2177561 and WO 97/30501 also describe arc detection systems.

### BRIEF SUMMARY OF THE INVENTION

It is an object of the present invention to provide an alternative method and system for detecting arcing.

According to one aspect of the present invention there is provided a system for detecting arc faults in an electrical circuit, the system including a store of a plurality of temporal models of electrical events associated with arc faults and of events not associated with arc faults, means for extracting from the circuit electrical signals associated with electrical events in the circuit, means for processing the signals into a form suitable for comparison with the models, and means for comparing the processed signals with the models to determine whether the event giving rise to the signals is an arc fault or not.

The means for extracting electrical signals may include a current sensor and means for providing an indication of voltage. The system may include a circuit breaker, the system being arranged to open the circuit breaker when an arc fault is detected. The temporal models may be in the form of templates or stochastic models.

According to another aspect of the present invention there is provided a system including an artificial neural net programmed to recognise features of different arcs so as to enable arcs caused by faults in the circuit to be distinguished from other arcs.

According to a further aspect of the present invention there is provided a method of detecting an arc fault in a circuit including the steps of extracting signals from the circuit, processing the signals into a form suitable for comparison, comparing the processed signals with a plurality of stored temporal models representative of both arc faults and events not associated with arc faults, and providing an output in accordance therewith.

The temporal models may be in the form of templates or stochastic models.

According to a fourth aspect of the present invention there is provided a method of detecting an arc fault in a circuit including the steps of extracting signals from the circuit, processing the signals into a form suitable for comparison, supplying the processed signals to an artificial neural net programmed to recognise features of different arcs so as to enable arcs caused by faults in the circuit to be distinguished from other arcs and providing an output in accordance therewith.

The extracted signals may be representative of current or voltage in the circuit. The method preferably includes the step of supplying the output to a circuit breaker to open the circuit breaker when an arc fault is detected.

According to a fifth aspect of the present invention there is provided a system for performing a method according to the further or fourth aspect of the present invention.

A system and method according to the present invention, will now be described, by way of example, with reference to the accompanying drawing.

### BRIEF DESCRIPTION OF THE DRAWING

The drawing is a schematic diagram of the system.

### DETAILED DESCRIPTION OF THE PREFERRED EMBODIMENT

The system includes a power generator 1 connected to a load 2 via a transmission line 3 including a circuit breaker 4 and a current transducer 5. The system also includes arc detection apparatus indicated generally by the numeral 10 connected to receive an output from the current transducer 5 and a voltage output from the generator 1 via line 11. The arc detection apparatus provides an output on line 12 to control operation of the circuit breaker 4, that is, to open the breaker when it detects an arc fault.

The arc detection apparatus 10 includes a voltage conditioning unit 13, which receives the voltage output on line 11, and a current conditioning unit 14, which receives the output from the current transducer 5. The voltage and current conditioning units 13 and 14 each provide output signals to a digital signal processing unit 15. The digital processing unit 15 also receives input signals from a memory 16.

The memory 16 contains temporal models of arc events and load characteristics, these may be in the form of templates or stochastic models and contain information about various arc features characteristic of arc faults and of false trip events. These templates can contain any number of electrical, mathematical or spectral features, such as accumulated differential of voltage and/or current and a high frequency spectrum, to form an arc feature set. The templates or models can be calculated over various time periods, such as a single half cycle or over a group of whole cycles of the voltage or current waveform. Standard training algorithms exist for calculating a Markov model (such as, Baum re-estimation). The Markov model can encapsulate temporal information to improve discrimination, such as to enable discrimination between repetitive commutator motor signatures and true arc fault events.

In operation, the voltage and current conditioning units 13 and 14 extract the discriminative arc features from their inputs and supply these to the processing unit 15. In the processing unit 15 these features are matched against the stored models in the memory 16 using a classification algorithm. The algorithm determines whether the detected arc features are characteristic of a true arc fault, such as caused by insulation breakdown, or are characteristic of non-fault arcs, such as motor commutator arcs. The processing unit 15 may calculate probabilities of occurrence of each arc model over time. These may be linked to an arc probability threshold so that the more commonly occurring events can be recognised rapidly. Where non-fault arc events have similar characteristics to fault signals, more detailed models can be created to ensure accurate discrimination between the two.

In normal operation, the power generator 1 supplies power to the load 2 via the transmission line 3. When the processing unit 15 detects a true fault arc it supplies a signal on line 12 to open the circuit breaker 4 and, hence, disconnect supply of power to the load and the associated transmission line 3. Alternatively, the processing unit 15 could be arranged to supply an output to an alarm, a maintenance recorder or to some external circuit to indicate that a fault has occurred.

Instead of storing stochastic models in the memory 16, an artificial neural net can be used. This would be taught to recognise arc signatures of different origins as represented by groups of features of the signatures.

What we claim is:

1. A system for detecting arc faults in an electrical circuit, wherein the system comprises: a store of a plurality of temporal models of electrical events associated with arc faults and of events not associated with arc faults; an interconnection for extracting from said circuit electrical signals associated with electrical events in said circuit; a processor for processing the signals into a form suitable for comparison with said models; and a comparator for comparing the processed signals with said models to determine whether the event giving rise to said signals is an arc fault or not.

2. A system according to claim 1, wherein said interconnection for extracting electrical signals includes a current sensor.

3. A system according to claim 1, wherein said interconnection for extracting electrical signals provides an indication of voltage.

4. A system according to claim 1 including a circuit breaker, and wherein said system is arranged to open said circuit breaker when an arc fault is detected.

5. A system according to claim 1, wherein said temporal models are in the form of templates.

6. A system according to claim 1, wherein said temporal models are in the form of stochastic models.

7. A system for detecting arc faults in an electrical circuit, wherein said system includes an artificial neural net programmed to recognise features of different arcs so as to enable arcs caused by faults in said circuit to be distinguished from other arcs.

8. A system for detecting arc faults in an electrical circuit, wherein said system comprises: a store of a plurality of temporal models of electrical events associated with arc faults and of events not associated with arc faults; a current sensor for extracting from said circuit signals representative of current in said circuit; an output of voltage in said circuit; a processor for processing the current and voltage signals into a form suitable for comparison with said models; and a comparator for comparing the processed signals with said models to determine whether the event giving rise to said signals is an arc fault or not.

9. A system for detecting arc faults in an electrical circuit, said system comprising: a store of a, plurality of temporal models of electrical events associated with arc faults and of events not associated with arc faults; means for extracting from said circuit electrical signals associated with electrical events in said circuit; means for processing said signals into a form suitable for comparison with said models; and means for comparing the processed signals with said models to determine whether the event giving rise to said signals is an arc fault or not.

10. A method of detecting an arc fault in a circuit comprising the steps of: extracting signals from said circuit; processing said signals into a form suitable for comparison; comparing the processed signals with a plurality of stored temporal models representative of both arc faults and of events not associated with arc faults; and providing an output in accordance therewith.

11. A method according to claim 10, wherein said temporal models are in the form of templates.

12. A method according to claim 10, wherein said temporal models are in the form of stochastic models.

13. A method according to claim 10, wherein the extracted signals are representative of current in said circuit.

14. A method according to claim 10, wherein the extracted signals are representative of voltage in said circuit.

15. A method according to claim 10 including the step of supplying said output to a circuit breaker to open said circuit breaker when an arc fault is detected.

16. A method of detecting an are fault in a circuit comprising the steps of: extracting signals from said circuit; processing signals into a form suitable for comparison; supplying the processed signals to an artificial neural net programmed to recognise features of different arcs so as to enable arcs caused by faults in said circuit to be distinguished from other arcs; and providing an output in accordance therewith.

17. A method according to claim 16 including the step of supplying the output to a circuit breaker to open said circuit breaker when an arc fault is detected.

18. A method of detecting an arc fault in a circuit comprising the steps of: extracting current and voltage signals from said circuit; processing said signals into a form suitable for comparison; comparing the processed signals with a plurality of stored temporal models representative of both arc faults and of events not associated with arc faults; and providing an output in accordance therewith to a circuit breaker in order to open said circuit breaker when an arc fault is detected.
